(19) United States
(12) Patent Application Publication
(10) Pub. No.: US 2021/0348957 A1
(43) Pub. Date: Nov. 11, 2021

(54) AIR FLOW RATE MEASUREMENT DEVICE

(71) Applicant: DENSO CORPORATION, Kariya-city (JP)

(72) Inventor: Kengo ITOU, Kariya-city (JP)

(21) Appl. No.: 17/381,876

(22) Filed: Jul. 21, 2021

Related U.S. Application Data
(63) Continuation of application No. PCT/JP2020/019487, filed on May 15, 2020.

(30) Foreign Application Priority Data
Jun. 5, 2019 (JP) 2019-105403

(51) Int. Cl. G01F 1/60; H05K 1/18; H05K 3/04

(52) U.S. Cl. CPC G01F 1/60; H05K 2201/10151; H05K 3/043; H05K 1/181

(57) ABSTRACT

A housing includes a measurement passage through which a part of air flowing in a main passage flows. A sensor assembly is fixed on the housing and includes a circuit board. A detection element configured to output a signal in response to a flow rate of air flowing in the measurement passage and an electronic component configured to drive the detection element are mounted on the circuit board. An outer edge of the circuit board has a fractured part with a fractured shape and a cut part having a surface roughness smaller than that of the fractured part. The fractured part at the outer edge of the circuit board is not arranged in the measurement passage but provided at a position excluding the measurement passage.

### CROSS REFERENCE TO RELATED APPLICATION

The present application is a continuation application of International Patent Application No. PCT/JP2020/019487 filed on May 15, 2020, which designated the U.S. and claims the benefit of priority from Japanese Patent Application No. 2019-105403 filed on Jun. 5, 2019. The entire disclosures of all of the above applications are incorporated herein by reference.

### TECHNICAL FIELD

The present disclosure relates to an air flow rate measurement device.

### BACKGROUND

An air flow rate measurement device is arranged at a main passage and configured to measure a flow rate of air flowing in the main passage. The air flow rate measurement device includes a housing and a sensor assembly, in which a detection element configured to output a signal in accordance with the flow rate of air, an electronic component configured to drive the detection element, and the like are mounted on a circuit board.

### SUMMARY

According to one aspect of the present disclosure, an air flow rate measurement device configured to measure a flow rate of air flowing in a main passage includes a housing and a sensor assembly. The housing includes a measurement passage through which a part of air flowing in the main passage flows. The sensor assembly is fixed on the housing, and includes a circuit board. A detection element configured to output a signal in accordance with a flow rate of air flowing in the measurement passage and an electronic component configured to drive the detection element are mounted on the circuit board. An outer edge of the circuit board includes a fractured part having a fractured shape and a cut part having a surface roughness smaller than that of the fractured part. The fractured part at the outer edge of the circuit board is not positioned in the measurement passage, and is provided at a position excluding the measurement passage.

### BRIEF DESCRIPTION OF DRAWINGS

FIG. 1 is a perspective view illustrating an air flow rate measurement device according to a first embodiment.

FIG. 2 is a perspective view illustrating the air flow rate measurement device viewed in a direction different from that in FIG. 1.

FIG. 3 is a cross-sectional view illustrating the air flow rate measurement device installed in a main flow duct according to the first embodiment.

FIG. 4 is a plan view illustrating a multi-piece board including circuit boards formed integrally with each other.

FIG. 5 is an explanatory view to explain a process to cut and separate each of the circuit boards from the multi-piece board.

FIG. 6 is a plan view illustrating the circuit board separated from the multi-piece board.

FIG. 7 is a view illustrating a sensor assembly fixed on a housing.

FIG. 8 is a cross-sectional view taken along a line VIII-VIII in FIG. 7.

FIG. 9 is an external view illustrating the housing to which a cover is attached.

FIG. 10 is a cross-sectional view taken along a line X-X in FIG. 9.

FIG. 11 is a flowchart for explaining a manufacturing method for the air flow rate measurement device according to the first embodiment.

FIG. 12 is a cross-sectional view illustrating an air flow rate measurement device according to a second embodiment.

FIG. 13 is a plan view illustrating a circuit board of an air flow rate measurement device according to a third embodiment.

FIG. 14 is a view illustrating a sensor assembly fixed on a housing in an air flow rate measurement device according to a fourth embodiment.

FIG. 15 is a cross-sectional view taken along a line XV-XV in FIG. 14.

FIG. 16 is an external view illustrating the housing to which a cover is attached.

FIG. 17 is a cross-sectional view taken along a line XVII-XVII in FIG. 16.

FIG. 18 is a view illustrating a sensor assembly fixed on a housing in an air flow rate measurement device according to a fifth embodiment.

FIG. 19 is a cross-sectional view taken along a line XIX-XIX in FIG. 18.

FIG. 20 is an external view illustrating an air flow rate measurement device according to a sixth embodiment, which includes a cover attached to a housing and coated with a potting agent.

FIG. 21 is a cross-sectional view taken along a line XXI-XXI in FIG. 20.

### DETAILED DESCRIPTION

To begin with, examples of relevant techniques will be described.

An air flow rate measurement device is arranged at a main passage and configured to measure a flow rate of air flowing in the main passage. The air flow rate measurement device includes a housing and a sensor assembly. The housing includes a measurement passage, and a part of air flowing in a main passage flows in the measurement passage. The sensor assembly includes a circuit board. A detection element configured to output a signal in accordance with the flow rate of air, an electronic component configured to drive the detection element, and the like are mounted on the circuit board. In the air flow rate measurement device, a part of the circuit board of the sensor assembly and the detection element mounted on the circuit board are arranged in the measurement passage of the housing.

Generally, in a manufacturing process for the circuit board of the sensor assembly, a multi-piece board including the circuit boards formed integrally with each other is manufactured, and the circuit boards are separated each other from the multi-piece board. At this point, a cut part and a fractured part are formed at an outer edge of the circuit board. The cut part is formed by being cut from the multi-piece board in a cutting process or the like. The fractured part is formed by being fractured by a pressing machine or the like. A dimensional accuracy of the fractured part at the outer edge of the circuit board depends on accuracy of a die of the pressing machine. When the die of the pressing machine is worn, the dimensional accuracy of the fractured part of the circuit board tends to be lowered. If the fractured part is arranged in the measurement passage of the housing without considering the position of the fractured part of the circuit board, issues described in following (1) and (2) may occur.

(1) When a passage resistance of the measurement passage is changed by dimensional variation in the fractured part of the circuit board, a flow rate characteristic of the air flowing in the measurement passage is changed, and detection accuracy of the flow rate of air is decreased.

(2) When the circuit board is made of a material including a glass fiber, the glass fiber may be frayed from the fractured part and fall in the measurement passage. If the glass fiber is attached to the detection element, a radiation amount of the detection element is changed. Then, the detection accuracy of the air flow rate is lowered, or the detection element may be broken.

As described above, in the air flow rate measurement device, in case where the circuit board of the sensor assembly is arranged in the measurement passage, if the position of the fractured part of the circuit board is not considered, the detection accuracy of the air flow rate may be decreased because of the dimensional variation of the fractured part or the like.

The present disclosure provides an air flow rate measurement device capable of improving detection accuracy of a flow rate of air.

According to one aspect of the present disclosure, an air flow rate measurement device configured to measure a flow rate of air flowing in a main passage includes a housing and a sensor assembly. The housing includes a measurement passage through which a part of air flowing in the main passage flows. The sensor assembly is fixed on the housing, and includes a circuit board. A detection element configured to output a signal in accordance with a flow rate of air flowing in the measurement passage and an electronic component configured to drive the detection element are mounted on the circuit board. An outer edge of the circuit board includes a fractured part having a fractured shape and a cut part having a surface roughness smaller than that of the fractured part. The fractured part at the outer edge of the circuit board is not positioned in the measurement passage, and is provided at a position excluding the measurement passage.

Accordingly, as the fractured part of the circuit board is not arranged in the measurement passage, even when a dimensional variation occurs at the fractured part, a flow rate characteristic of the air flowing in the measurement passage is not changed by the dimensional variation. In addition, even when the circuit board is made of a material including a glass fiber, as the glass fiber does not fall from the fractured part to the measurement passage, foreign matter is restricted from attaching to the detection element. Therefore, the air flow rate measurement device is enabled to restrict variation in quality and improve the accuracy of detecting the flow rate of air.

According to another aspect of the present disclosure, a method of manufacturing an air flow rate measurement device configured to measure a flow rate of air flowing in a main passage, includes the following processes:

forming a multi-piece board that includes circuit boards formed integrally with each other, the circuit board having a detection element configured to output a signal in accordance with a flow rate of air and an electronic component configured to drive the detection element;

forming a cut part at an outer edge of the circuit board by processing the multi-piece board;

forming a fractured part at the outer edge of the circuit board by fracturing a part of the multi-piece board at which the cut part is not formed so as to separate the circuit board;

forming a housing including a measurement passage in which a part of the air flowing in the main passage flows, by injection molding; and

fixing the circuit board to the housing by arranging the fractured part at a position excluding the measurement passage, not in the measurement passage, when or after forming the housing by the injection molding.

Accordingly, the manufacturing method is enabled to restrict variation in quality and improve the accuracy of detecting the flow rate of air, similarly to the air flow rate measurement device.

The reference numerals attached to the components and the like indicate an example of correspondence between the components and the like and specific components and the like in embodiments to be described below.

Embodiments of the present disclosure will be described below with reference to the drawings. Parts that are identical or equivalent to each other in the following embodiments are assigned the same reference numerals and will not be described.

### First Embodiment

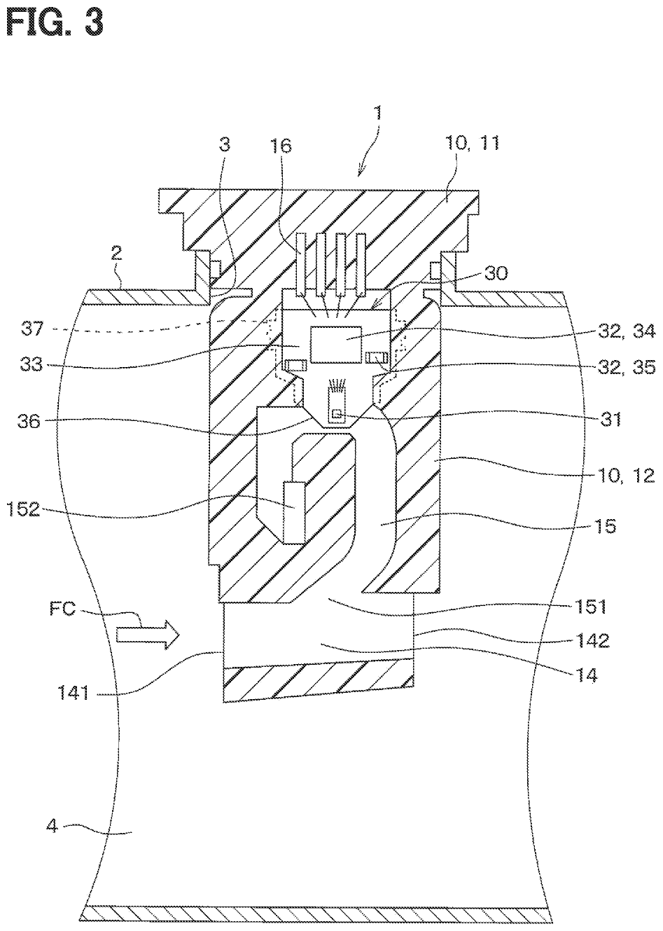

A first embodiment will be described with reference to the drawings. As shown in FIG. 3, an air flow rate measurement device 1 of the present embodiment is disposed in an insertion hole 3 provided at a main flow duct 2, and configured to measure a flow rate of air flowing through a main passage 4 formed in the main flow duct 2. Specifically, an air intake duct included in an air intake system of an engine system for a vehicle is exemplified as the main flow duct 2. In this case, the air flow rate measurement device 1 is used as an air flow meter to measure an intake amount of air sucked into an engine through the air intake duct. Information measured by the air flow meter is transmitted to an electronic control device (referred to as ECU hereinafter) of an unillustrated engine system. Based on the information, the ECU controls each section included in the engine system, for example, controls a fuel injection amount of an injector, an EGR amount, and the like. An arrow FC in FIG. 3 shows a flow direction of air flowing in the main passage 4.

The air flow rate measurement device 1 will be described below.

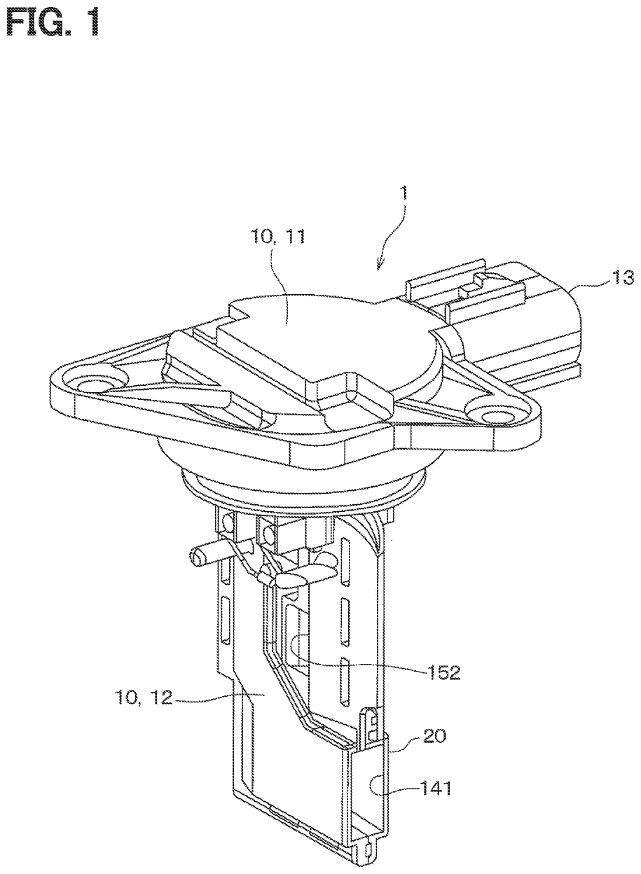

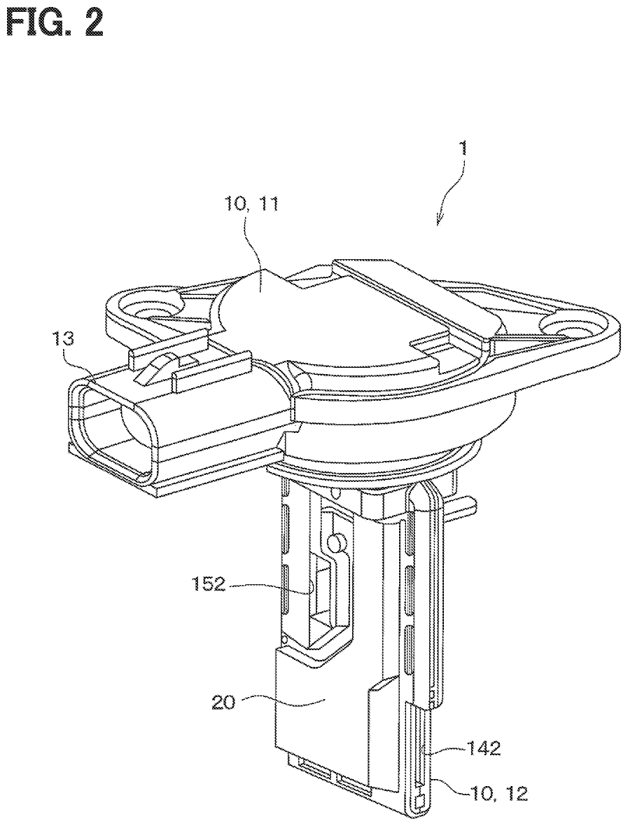

As shown in FIGS. 1 to 3, the air flow rate measurement device 1 includes a housing 10, a cover 20, and a sensor assembly 30.

The housing 10 includes a flange 11 and a housing body 12. The flange 11 and the housing body 12 are formed integrally with each other. The flange 11 is arranged radially outside the main flow duct 2. A connector 13 is provided at the flange 11.

The housing body 12 is arranged radially inside the main flow duct 2. The housing body 12 includes a sub-passage 14 through which the air flows, and a measurement passage 15 which branches from the sub-passage 14. The cover 20 is attached to the housing body 12. That is, the housing body 12 forms the sub-passage 14 and the measurement passage 15, with the cover 20.

In the housing body 12, the sub-passage 14 communicates a sub-passage inlet 141 provided at an upstream side in the flow direction with a sub-passage outlet 142 provided at a downstream side in the flow direction. A part of the air flowing in the main passage 4 flows into the sub-passage 14 through the sub-passage inlet 141. Subsequently, after passing through the sub-passage 14, the air flows out and returns to the main passage 4 through the sub-passage outlet 142.

The measurement passage 15 connects a measurement passage inlet 151 provided in a middle of the sub-passage 14 to a measurement passage outlet 152 provided at a side surface of the housing body 12 and a side surface of the cover 20. A part of the air flowing in the sub-passage 14 flows into the measurement passage 15 through the measurement passage inlet 151. Subsequently, after passing through the measurement passage 15, the air flows out and returns to the main passage 4 through the measurement passage outlet 152. That is, a part of the air flowing in the main passage 4 flows into the measurement passage 15. A cross-sectional area of the measurement passage 15 is smaller than that of the sub-passage 14.

When viewed from the upstream of the main passage 4, the sub-passage inlet 141 and the sub-passage outlet 142 are partially overlapped with each other, and the sub-passage 14 is formed substantially linearly. The measurement passage 15 is formed to branch from the sub-passage 14. If pollutants such as sand and dust contained in the air in the main passage 4 enters the sub-passage 14 through the sub-passage inlet 141, the pollutants are discharged mainly from the sub-passage outlet 142. Therefore, inflow of the pollutants into the measurement passage 15 can be restricted.

The sensor assembly 30 includes a circuit board 33 on which a detection element 31, an electronic component 32, and the like are mounted. The detection element 31 is configured to output a signal corresponding to the flow rate of the air flowing in the measurement passage 15. The electronic component 32 is arranged to drive the detection element 31. As the circuit board 33, for example, a glass epoxy board or the like is employed. The detection element 31 is, for example, a semiconductor element, a flap type element, a heat wire type element , or a Karman vortex type element. The electronic component 32 includes a control circuit 34 configured by an integrated circuit, and a capacitor 35 configured to reduce a power supply noise, which are mounted on the circuit board 33. The signal detected by the detection element 31 in accordance with a flow rate of air is transmitted to the ECU of the engine system through a terminal 16.

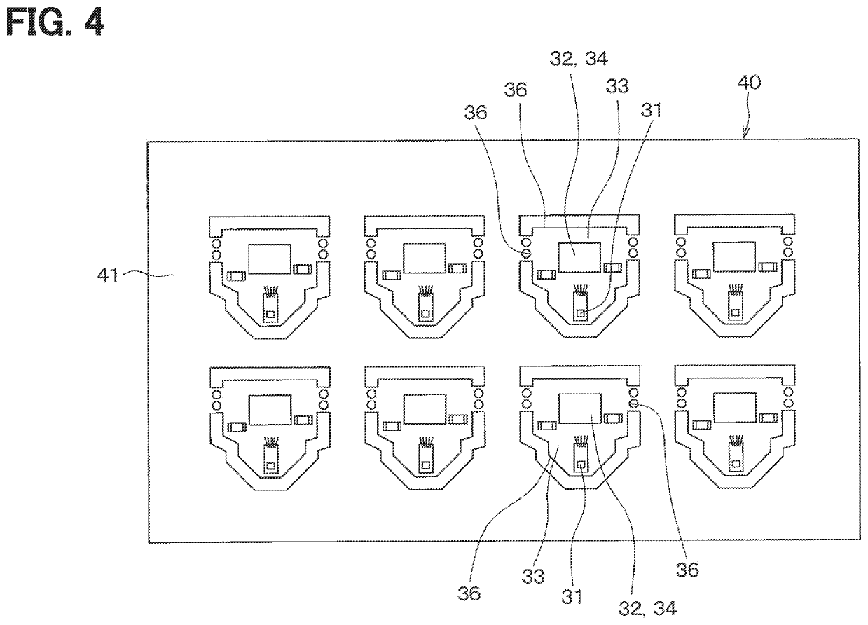

A process of manufacturing the circuit board 33 of the sensor assembly 30 will be described below. As shown in FIG. 4, in the manufacturing process of the circuit board 33, a multi-piece board 40 is manufactured. The multi-piece board 40 includes the circuit boards 33 formed integrally with each other, and the detection element 31, the electronic component 32 and the like are mounted on each of the circuit boards 33. In addition, a cut part 36 is formed at the multi-piece board 40 by being cut by a cutting process, laser machining, or the like. The cut part 36 is a part of an outer edge of each of the circuit boards 33.

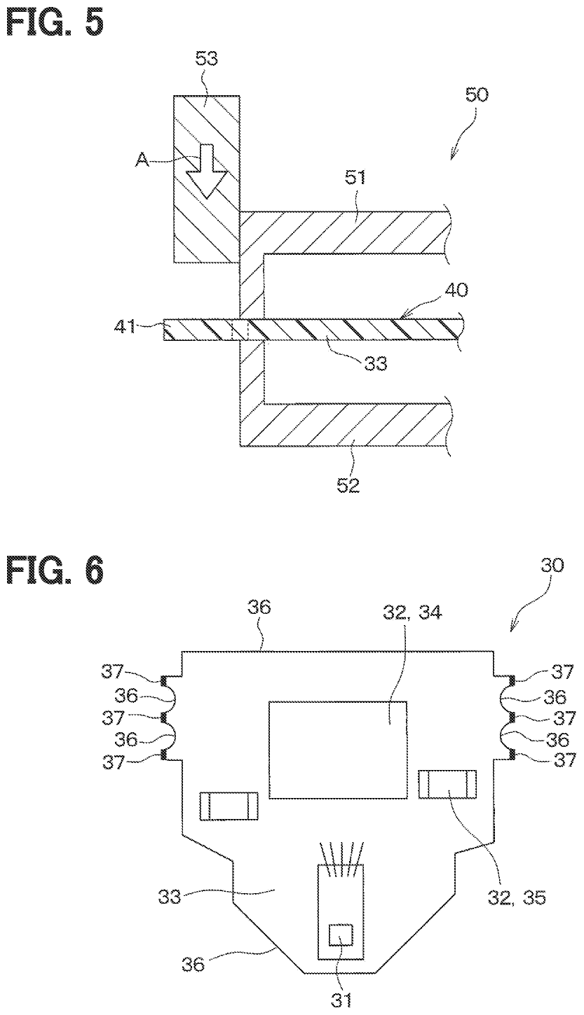

After that, the circuit boards 33 are separated from the multi-piece board 40. In this process, as shown in FIG. 5, the circuit board 33 to be separated from the multi-piece board 40 is fastened by a die part 51, 52 of a pressing machine 50 so as to hold the circuit board 33. After that, a die part 53 for punching is moved in a direction shown by an arrow A in FIG. 5, such that a discard board part 41 is fractured to separate each of the circuit boards 33 from the multi-piece board 40.

FIG. 6 shows one circuit board 33 separated from the multi-piece board 40. The outer edge of the circuit board 33 includes a fractured part 37 and the cut part 36. The fractured part 37 has a fractured shape. The cut part 36 has a surface roughness smaller than that of the fractured part 37. In FIG. 6, the fractured part 37 is indicated by a thick line. The fractured part 37 is a part of the outer edge of the circuit board 33 broken by the pressing machine 50. The cut part 36 is a part of the outer edge of the circuit board 33 cut from the multi-piece board 40 by the cutting process or the like.

In the manufacturing process of the circuit board 33 described above, dimensional accuracy of the fractured part 37 at the outer edge of the circuit board 33 depends on accuracy of the die parts of the pressing machine 50. Therefore, if the die part of the pressing machine 50 is worn, the dimensional accuracy of the fractured part 37 of the circuit board 33 may be reduced. The cross-sectional area of the measurement passage 15, in which a part of the circuit board 33 is arranged, is smaller than that of the sub-passage 14. Therefore, a dimensional variation of the fractured part 37 of the circuit board 33 greatly affects a flow rate characteristic of the air flowing in the measurement passage 15.

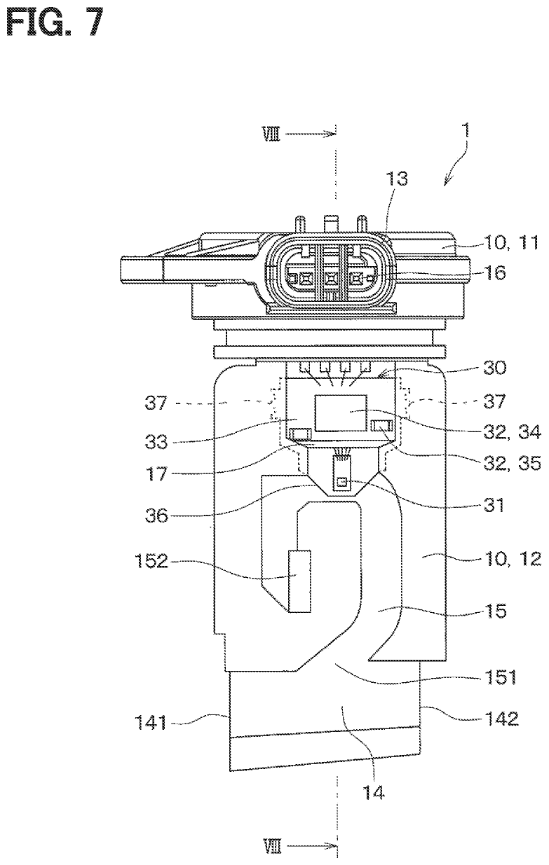

According to the present embodiment, as shown in FIG. 7, the circuit board 33 of the sensor assembly 30 is disposed at the measurement passage 15 of the housing 10 such that the fractured part 37 of the circuit board 33 is not positioned in the measurement passage 15 and is provided at a position excluding the measurement passage 15. Specifically, the circuit board 33 is fixed to the housing 10 such that a part of the outer edge of the circuit board 33 including the fractured part 37 is covered by a resin forming the housing 10. Therefore, the fractured part 37 of the circuit board 33 is not provided at the measurement passage 15. The cut part 36 at the outer edge of the circuit board 33 is provided at the measurement passage 15.

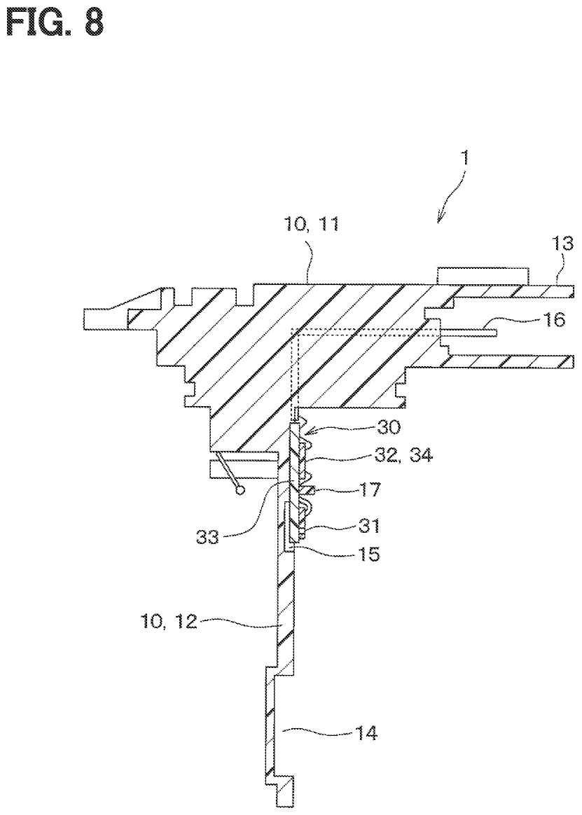

FIG. 8 is a cross-sectional view taken along a line VIII-VIII in FIG. 7. When the housing 10 is formed by injection molding, a partition wall 17 is formed on the circuit board 33. The partition wall 17 is formed integrally with the housing body 12.

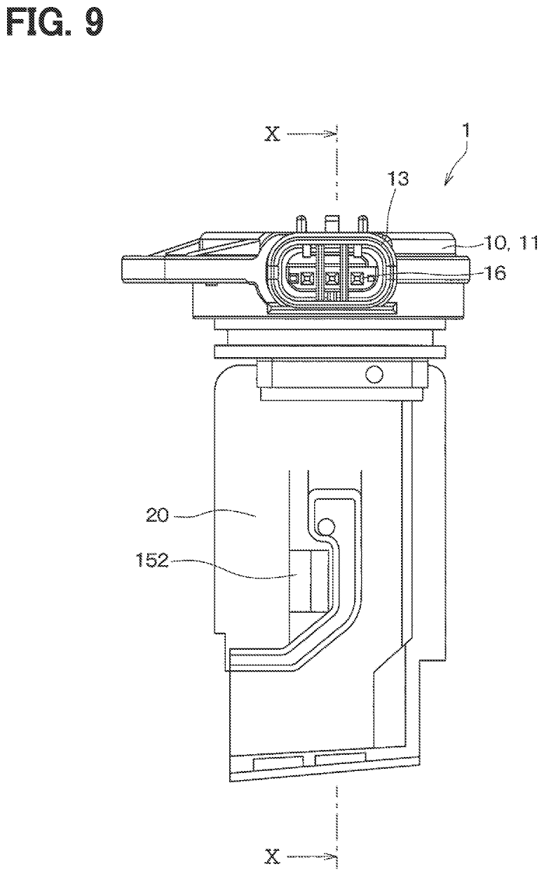

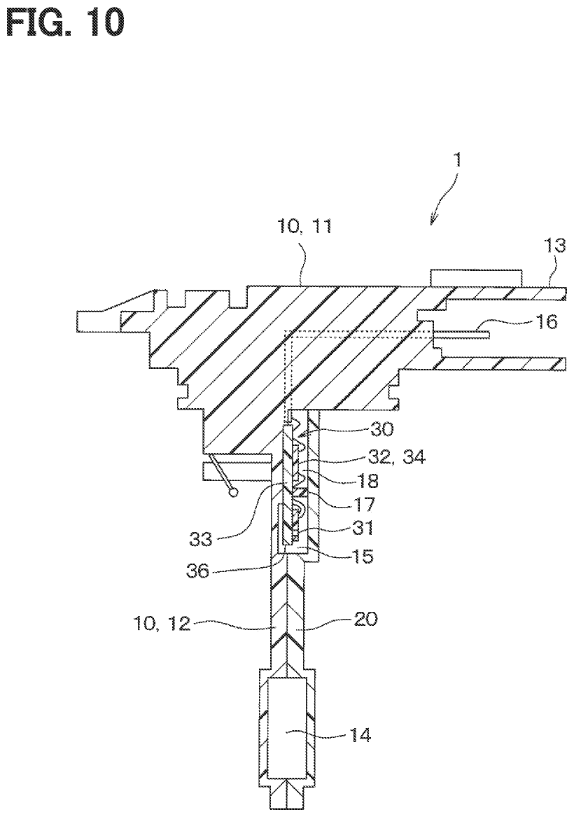

As shown in FIGS. 9 and 10, the cover 20 is attached to the housing body 12. At this time, a circuit chamber 18 is formed in the housing 10 and partitioned from the measurement passage 15 by the partition wall 17. The circuit chamber 18 is a space defined and closed by an inner wall of the housing body 12, the partition wall 17, and an inner wall of the cover 20. The circuit chamber 18 houses the control circuit 34, the capacitor 35, and the like, among the electronic component 32 mounted on the circuit board 33. On the other hand, the detection element 31 mounted on the circuit board 33 is disposed in the measurement passage 15. As the fractured part 37 at the outer edge of the circuit board 33 is not provided in the measurement passage 15, even when the dimensional variation occurs at the fractured part 37, the flow rate characteristic of the air flowing in the measurement passage 15 is not changed. Further, as a glass fiber included in the circuit board 33 does not fall from the fractured part 37 to the measurement passage 15, foreign matter is restricted from attaching to the detection element 31. Therefore, the air flow rate measurement device 1 is enabled to restrict a variation in quality and improve detection accuracy of the air flow rate.

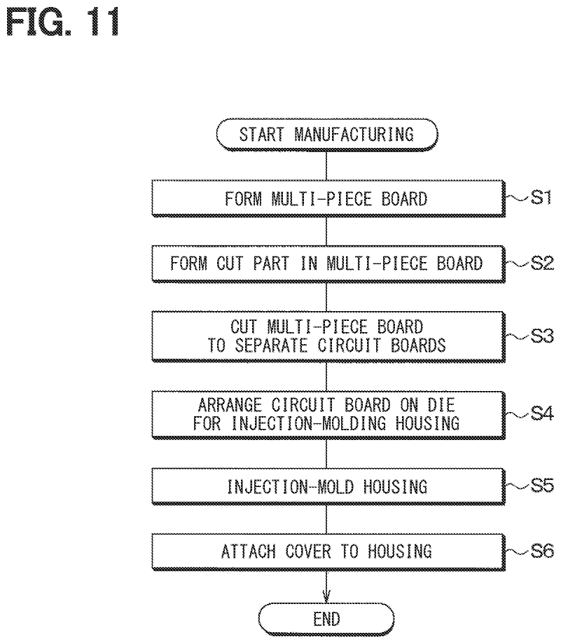

A manufacturing method for the air flow rate measurement device 1 will be described with reference to a flow chart shown in FIG. 11.

In the manufacturing method for the air flow rate measurement device 1, at step S1, the multi-piece board 40 is formed so as to integrally include the circuit boards 33 on each of which the detection elements 31, the electronic components 32, and the like are mounted, as shown in FIG. 4.

After that, at step S2, cutting process is performed on the multi-piece board 40 to form the cut part 36 of the circuit board 33. In the cutting process, a router, a drill, or a laser machining can be used. In the cutting process, a part of the circuit board 33, at which the fractured part 37 will be formed, may be shaved to decrease the thickness of the circuit board 33.

Next, at step S3, the pressing machine 50 fractures the multi-piece board 40 at the positions where the cut part 36 is not formed to separate the circuit boards 33 from each other, as shown in FIGS. 5 and 6. At this point, the fractured part 37 having the fractured shape is formed at the outer edge of the circuit board 33.

Next, at step S4, the circuit board 33 is put on an unillustrated injection molding die to mold the housing 10 by injection molding. At this point, the fractured part 37 at the outer edge of the circuit board 33 is not positioned at the measurement passage 15, and provided at the position excluding the measurement passage 15 in the housing 10.

After that, at step S5, molten resin is injected to the injection molding die and solidified by being cooled to mold the housing 10 by the injection molding. As a result, as shown in FIGS. 7 and 8, by the injection molding to mold the housing 10, the fractured part 37 at the outer edge of the circuit board 33 is covered by the housing 10, and the circuit board 33 is fixed to the housing 10. That is, the housing 10 covers at least the fractured part 37 in the circuit board 33 with the resin. Therefore, the fractured part 37 at the outer edge of the circuit board 33 is not positioned at the measurement passage 15 of the housing 10, while the cut part 36 is positioned at the measurement passage 15 of the housing 10.

After that, at step S6, the cover 20 is attached to the housing body 12 as shown in FIGS. 9 and 10. As a result, the sub-passage 14, the measurement passage 15, and the circuit chamber 18 are formed by the housing 10 and the cover 20, so that the manufacturing of the air flow rate measurement device 1 is completed.

The manufacturing method for the air flow rate measurement device 1 described above offers the following effects.

(1) In the first embodiment, the fractured part 37 at the outer edge of the circuit board 33 is not positioned in the measurement passage 15, and is provided at the position excluding the measurement passage 15. Because of this, the flow rate characteristic of the air flowing in the measurement passage 15 is not changed by the dimensional variation of the fractured part 37. Further, as a glass fiber included in the circuit board 33 does not fall from the fractured part 37 to the measurement passage 15, foreign matter is restricted from attaching to the detection element 31. Therefore, the air flow rate measurement device 1 is enabled to restrict variation in quality and improve detection accuracy of the air flow rate.

(2) In the first embodiment, the cut part 36 at the outer edge of the circuit board 33 is provided at the measurement passage 15 in the housing 10. As the cut part 36 of the circuit board 33 has a high dimensional accuracy, the flow rate characteristic of the air flowing in the measurement passage 15 is not changed. Further, the glass fiber included in the circuit board 33 does not fall from the cut part 36. Therefore, the air flow rate measurement device 1 is enabled to restrict variation in quality and improve detection accuracy of the air flow rate.

(3) In the first embodiment, the fractured part 37 at the outer edge of the circuit board 33 is covered by the resin forming the housing 10. Because of this, the flow rate characteristic of the air flowing in the measurement passage 15 is restricted from being changed, as the fractured part 37 of the circuit board 33 is not positioned at the measurement passage 15. Further, as the glass fiber included in the circuit board 33 does not fall from the fractured part 37, the foreign matter is restricted from attaching to the detection element 31.

(4) In the first embodiment, the control circuit 34 and the capacitor 35 of the electronic component 32 mounted on the circuit board 33 are disposed in the circuit chamber 18. As a result, as the electronic component 32 disposed in the circuit chamber 18 is not exposed to the air flowing in the measurement passage 15, corrosion of the electronic component 32 is restricted, and reliability of the measurement accuracy can be improved.

### Second Embodiment

A second embodiment will be described below. The second embodiment is similar to the first embodiment except for a part of the configurations of the housing 10 and the cover 20. Accordingly, only the difference from the first embodiment will be described below.

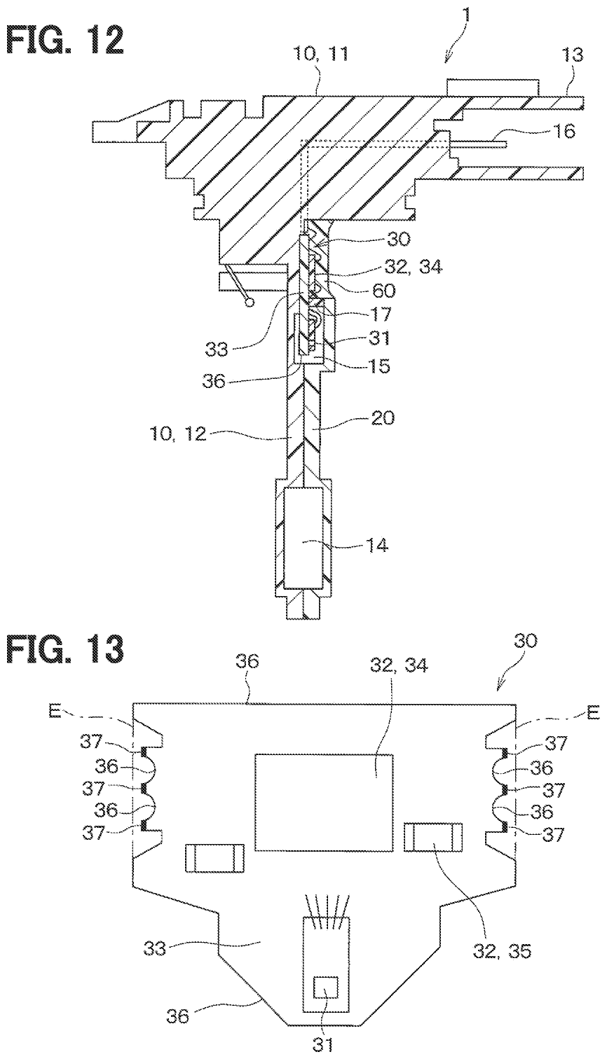

As shown in FIG. 12, in the second embodiment, a surface of the circuit board 33, on which the control circuit 34 and the capacitor 35 of the electronic component 32 are mounted, is sealed with a potting agent 60. The potting agent 60 is provided between the partition wall 17 and a lower surface of the flange 11. The cover 20 is not provided on the potting agent 60. Therefore, the potting agent 60 is exposed to the main passage 4. Accordingly, it is possible to improve heat dissipation of the control circuit 34.

In the second embodiment, as the surface of the circuit board 33, on which the control circuit 34 and the capacitor 35 are mounted, is sealed by the potting agent 60, the control circuit 34 and the capacitor 35 of the electronic component 32 are restricted from being exposed to the air. Therefore, in the second embodiment, it is possible to restrict the corrosion of the electronic component 32 mounted on the circuit board 33 and improve the reliability of the measurement accuracy.

In the second embodiment, similarly to the first embodiment, the fractured part 37 at the outer edge of the circuit board 33 is covered by the resin forming the housing 10. Because of this, the fractured part 37 at the outer edge of the circuit board 33 is not positioned at the measurement passage 15. Therefore, in the air flow rate measurement device 1 according to the second embodiment, it is possible to restrict variation in the quality and improve the detection accuracy of the air flow rate.

### Third Embodiment

A third embodiment will be described below. The third embodiment is similar to the first embodiment or the like except for a part of the shape of the circuit board 33, so only the difference from the first embodiment and the like will be described below.

FIG. 13 is a plan view illustrating a sensor assembly 30 included in an air flow rate measurement device 1 of the third embodiment. In the third embodiment, the outer edge of the circuit board 33 of the sensor assembly 30 includes the fractured part 37 and the cut part 36. In FIG. 13, the fractured part 37 is indicated by a thick line.

In the third embodiment, the cut part 36 is positioned at an outermost edge of the circuit board 33. The fractured part 37 is provided at a position recessed inward from a virtual line connecting the outermost edges of the circuit board 33. For explanation, in FIG. 13, a dashed-dotted line E indicates the virtual line connecting the outermost edges of the circuit board 33. The fractured part 37 is provided at a position recessed inward from the dashed-dotted line E.

In the third embodiment, similarly to the first embodiment or the like, the part of the circuit board 33 including the fractured part 37 at the outer edge is covered by the resin forming the housing 10. Therefore, in the third embodiment, when the circuit board 33 is put on the unillustrated die to mold the housing 10 by the injection molding, even in a case that the dimensional variation occurs at the fractured part 37 of the circuit board 33, contact and interference between the fractured part 37 and the injection molding die can be reduced.

### Fourth Embodiment

A fourth embodiment will be described below. The fourth embodiment is similar to the first embodiment or the like except for a method of fixing between the housing 10 and the circuit board 33, accordingly, only difference from the first embodiment or the like will be described below.

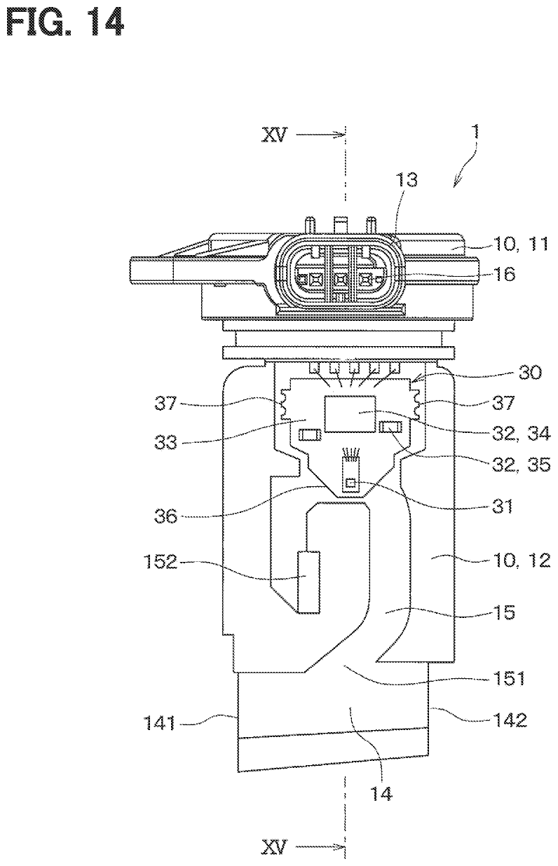

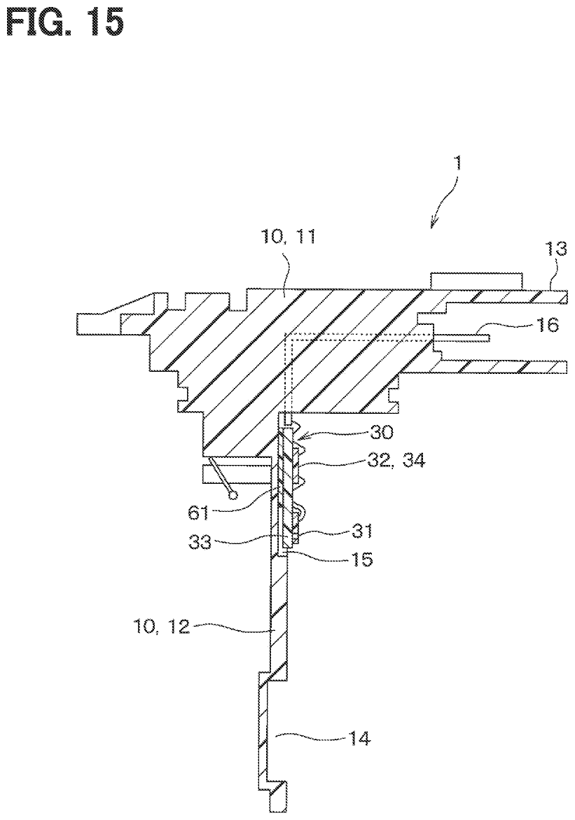

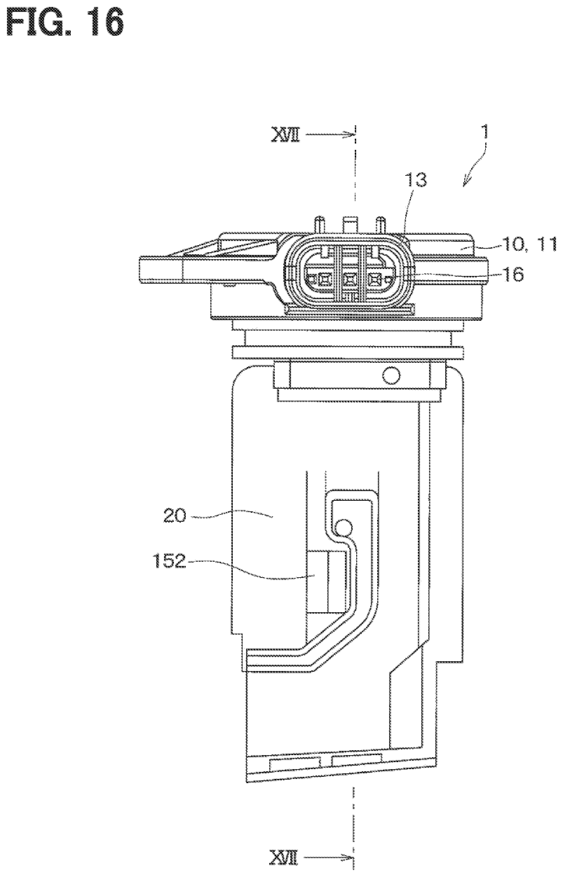

As shown in FIGS. 14 and 15, in the fourth embodiment, the circuit board 33 is fixed to an inner wall of the housing 10 by an adhesive 61. In this case, the circuit board 33 may be fixed to the inner surface of the housing 10 by the adhesive 61 after forming the housing 10 by the injection molding. Therefore, the circuit board 33 can be restricted from receiving the stress of resin forming the housing 10 by the injection molding.

The adhesive 61 fixing the circuit board 33 to the inner wall of the housing 10 is preferred to have a predetermined elasticity. In this case, even when the housing 10 expands or shrinks because of change in temperature of the air flowing in the main passage 4, the stress applied on the circuit board 33 from the housing 10 is restricted by the adhesive 61.

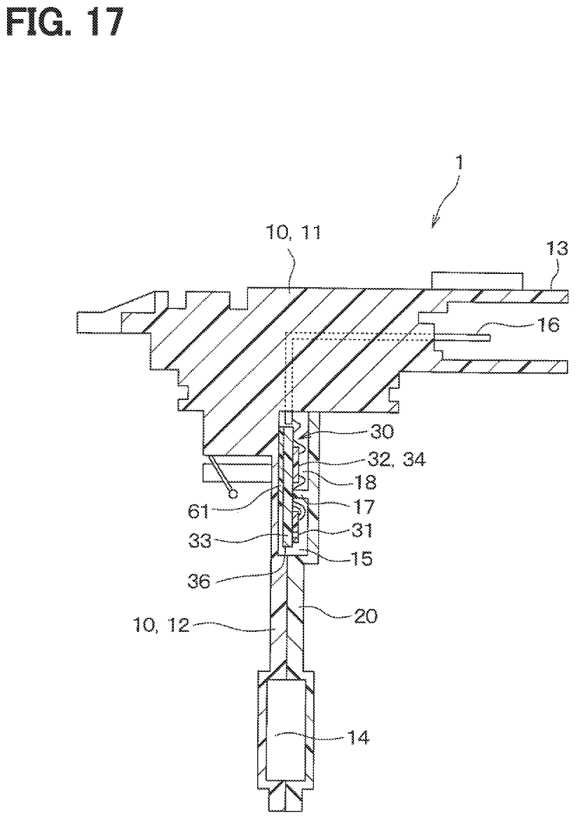

As shown in FIGS. 16 and 17, in the fourth embodiment, the partition wall 17 formed integrally with the cover 20 partitions the measurement passage 15 and the circuit chamber 18 from each other. The fractured part 37 at the outer edge of the circuit board 33 is not positioned at the measurement passage 15 and is positioned in the circuit chamber 18. The cut part 36 at the outer edge of the circuit board 33 is provided at the measurement passage 15. Because of the above configuration, even when the dimensional variation occurs at the fractured part 37 of the circuit board 33, the flow rate characteristic of the air flowing in the measurement passage 15 is not changed by the dimensional variation of the fractured part 37. Further, if the glass fiber included in the circuit board 33 falls from the fractured part 37, the foreign matter does not enter the measurement passage 15 from the circuit chamber 18. Thus, the foreign matter is restricted from attaching to the detection element 31. According to the fourth embodiment, similarly to the first embodiment or the like described above, the air flow rate measurement device 1 is enabled to restrict variation in the quality and improve the detection accuracy of the air flow rate.

### Fifth Embodiment

A fifth embodiment will be described below. The fifth embodiment is similar to the first embodiment or the like except for a fixing method between the housing 10 and the circuit board 33, accordingly, only difference from the first embodiment or the like will be described below.

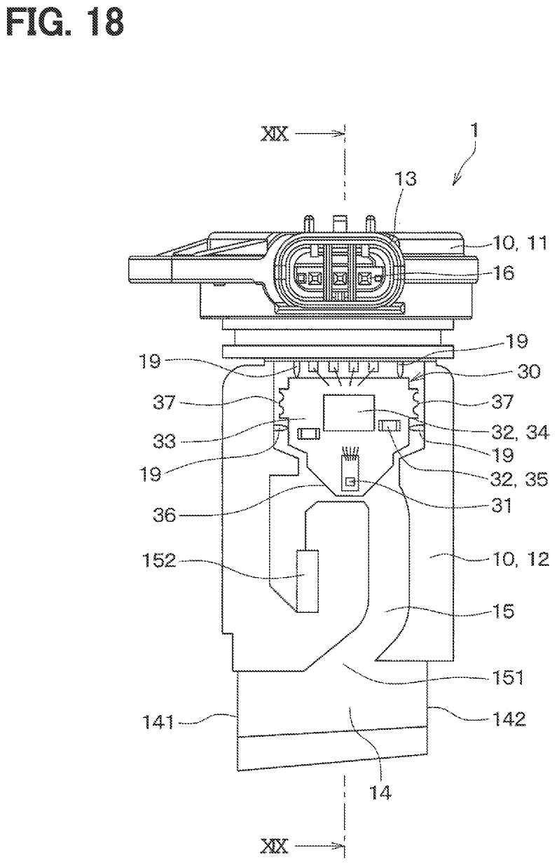

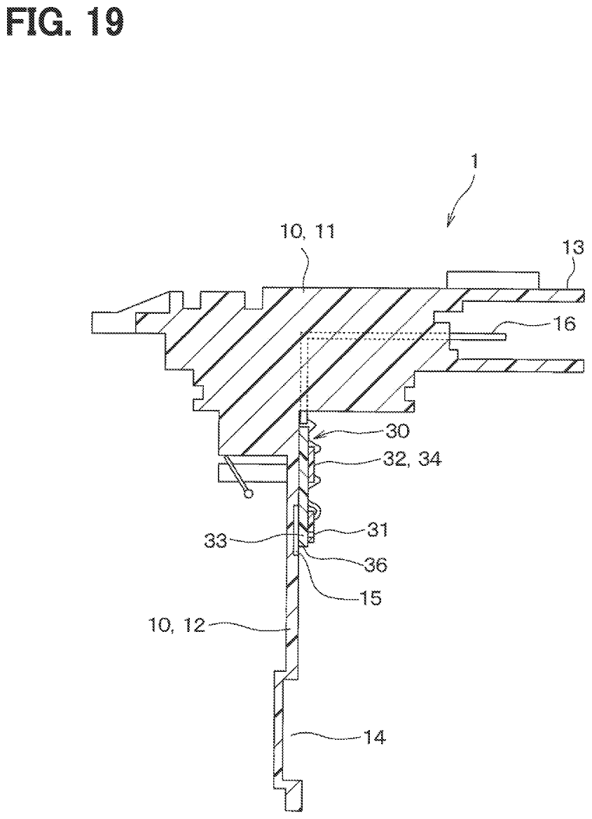

As shown in FIGS. 18 and 19, in the fifth embodiment, the housing 10 includes protrusions 19 at an inner wall surface defining the circuit chamber 18. The circuit board 33 is fixed by being press-fitted with the protrusions 19. The positions, the number, the shape, and the like of the protrusions 19 can be arbitrarily set. In the fifth embodiment, the number of parts can be reduced by forming the protrusions 19 integrally with the housing 10 to press-fit the circuit board 33. In addition, positional accuracy of the circuit board 33 with respect to the housing 10 can be improved.

Further, in the fifth embodiment, the circuit board 33 may be fixed by being press-fitted with the protrusions 19 of the housing 10 after forming the housing 10 by the injection molding. Therefore, when forming the housing 10 by the injection molding, the circuit board 33 can be restricted from receiving the stress of resin.

In the fifth embodiment, the fractured part 37 at the outer edge of the circuit board 33 is not provided at the measurement passage 15, and is provided in the circuit chamber 18. The cut part 36 at the outer edge of the circuit board 33 is provided at the measurement passage 15. Therefore, according to the fifth embodiment, similarly to the first embodiment or the like described above, the air flow rate measurement device 1 is enabled to restrict variation in the quality and improve the detection accuracy of the air flow rate.

### Sixth Embodiment

A sixth embodiment will be described below. The sixth embodiment is a combination of the second embodiment and the fourth embodiment.

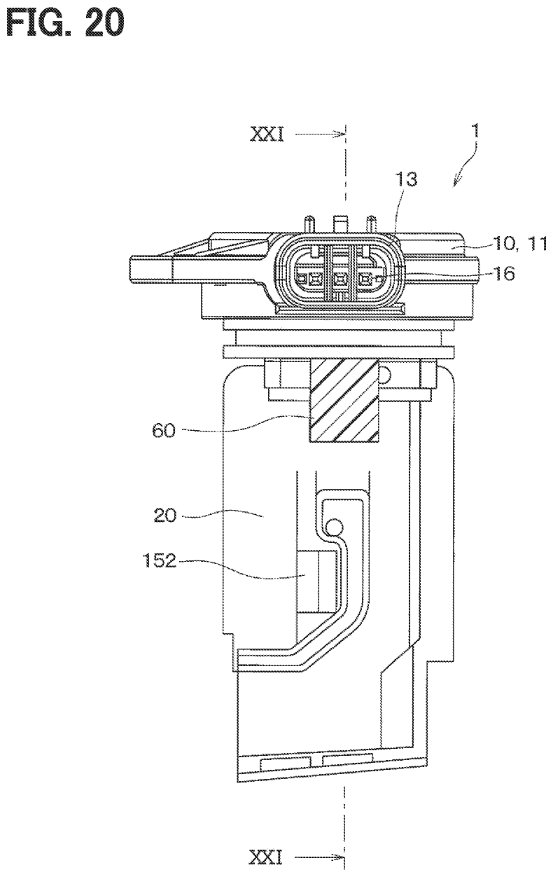

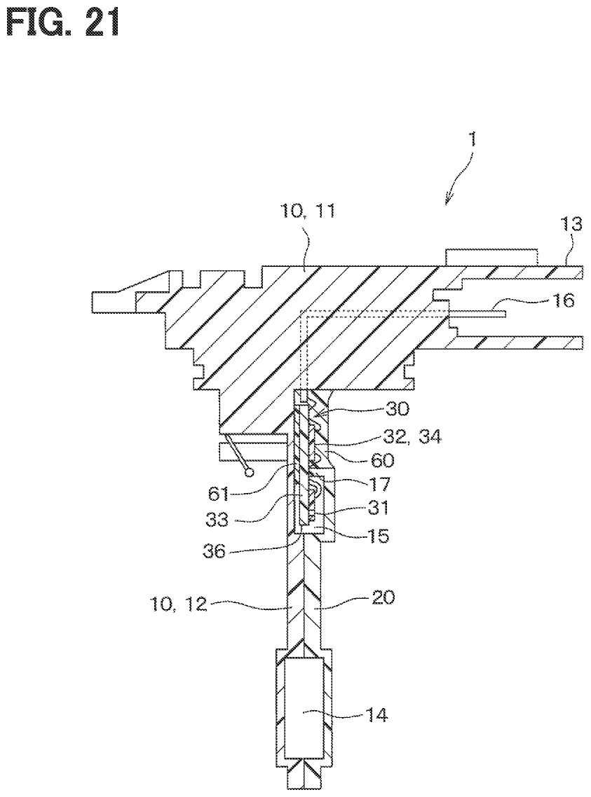

As shown in FIGS. 20 and 21, in the sixth embodiment, the circuit board 33 is fixed to the inner wall of the housing 10 by the adhesive 61. Further, in the sixth embodiment, the surface of the circuit board 33, on which the control circuit 34 and the capacitor 35 are mounted, is sealed with the potting agent 60. The potting agent 60 is provided between the partition wall 17 and a lower surface of the flange 11. The cover 20 is not provided over the potting agent 60. Therefore, the potting agent 60 is exposed to the main passage 4. In FIG. 20, an area marked by hatching indicates the potting agent 60 exposed to the main passage 4, but does not indicate a cross-section.

In the sixth embodiment, the surface of the circuit board 33, on which the control circuit 34 and the capacitor 35 are mounted, is sealed with the potting agent 60. Therefore, the corrosion of the control circuit 34 and the capacitor 35 of the electronic component 32 mounted on the circuit board 33 is restricted, and the reliability of the measurement accuracy can be improved.

In the sixth embodiment, the fractured part 37 at the outer edge of the circuit board 33 is not provided at the measurement passage 15, and is provided at the position excluding the measurement passage 15. The fractured part 37 at the outer edge of the circuit board 33 is sealed with the potting agent 60. The cut part 36 at the outer edge of the circuit board 33 is provided at the measurement passage 15. Therefore, according to the sixth embodiment, similarly to the first embodiment or the like described above, it is possible to restrict variation in the quality and improve the detection accuracy of the air flow rate.

### Other Embodiments

The present disclosure is not limited to the embodiments described above, and can be modified as appropriate. The above embodiments are not independent of each other, and can be appropriately combined except when the combination is obviously impossible. The constituent element(s) of each of the above embodiments is/are not necessarily essential unless it is specifically stated that the constituent element(s) is/are essential in the above embodiment, or unless the constituent element(s) is/are obviously essential in principle. A quantity, a value, an amount, a range, or the like referred to in the description of the embodiments described above is not necessarily limited to such a specific value, amount, range or the like unless it is specifically described as essential or understood as being essential in principle. The shape, the positional relationship, and the like of a component or the like mentioned in the above embodiments are not limited to those being mentioned unless otherwise specified, limited to specific shape, positional relationship, and the like in principle, or the like.

(1) In the embodiments, the air intake duct included in the air intake system of the engine system for the vehicle is described as the main flow duct 2 at which the air flow rate measurement device 1 is arranged. However, the present disclosure is not limited to this. The air flow rate measurement device 1 may be used for various purposes in order to measure the flow rate of the air flowing in the main passage 4 of the main flow duct 2.

(2) In the embodiments, the housing 10 of the air flow rate measurement device 1 includes the sub-passage 14 through which the air flows and the measurement passage 15 branched from the sub-passage 14. However, the present disclosure is not limited to this. The housing 10 may include only the measurement passage 15 through which a part of the air in the main passage 4 flows. Further, the shapes of the housing 10, the sub-passage 14, the measurement passage 15, the circuit chamber 18, and the like described in the embodiments can be arbitrarily changed.

(3) In the embodiments, the cover 20 of the air flow rate measurement device 1 includes a part of the sub-passage 14 and a part of the measurement passage 15, however, the present disclosure is not limited to this. The cover 20 may be a plate having a flat shape.

(4) In the embodiments, the detection element 31, the electronic component 32, and the like are mounted on the multi-piece board 40, however, the present disclosure is not limited to this. The detection element 31, the electronic component 32, and the like may be mounted on the circuit board 33 after separated from the multi-piece board 40.

(5) In the embodiments, the fractured part 37 is provided at left and right sides of the circuit board 33, however, the present disclosure is not limited to this. The position, the shape, the number, and the like of the fractured part 37 can be set arbitrarily. In addition, the shape of the circuit board 33 and the arrangement of the electronic component 32 may be set arbitrarily.

What is claimed is:

1. An air flow rate measurement device configured to measure a flow rate of air flowing in a main passage, comprising:
a housing that includes a measurement passage through which a part of the air flowing in the main passage flows; and
a sensor assembly fixed on the housing and including a circuit board on which a detection element and an electronic component are mounted, the detection element outputting a signal in response to a flow rate of air flowing in the measurement passage, the electronic component driving the detection element, wherein
an outer edge of the circuit board includes a fractured part having a fractured shape and a cut part having a surface roughness smaller than that of the fractured part,
the fractured part at the outer edge of the circuit board is not arranged in the measurement passage but provided at a position excluding the measurement passage,
the housing includes a circuit chamber partitioned from the measurement passage by a partition wall,
the fractured part is positioned in the circuit chamber, and
the circuit board is fixed on an inner wall of the housing by an adhesive.

2. An air flow rate measurement device configured to measure a flow rate of air flowing in a main passage, comprising:
a housing that includes a measurement passage through which a part of the air flowing in the main passage flows; and
a sensor assembly fixed on the housing and including a circuit board on which a detection element and an electronic component are mounted, the detection element outputting a signal in response to a flow rate of air flowing in the measurement passage, the electronic component driving the detection element, wherein
an outer edge of the circuit board includes a fractured part having a fractured shape and a cut part having a surface roughness smaller than that of the fractured part,
the fractured part at the outer edge of the circuit board is not arranged in the measurement passage but provided at a position excluding the measurement passage,
the housing includes a circuit chamber partitioned from the measurement passage by a partition wall,
the fractured part is positioned in the circuit chamber,
the housing includes a plurality of protrusions on an inner wall of the circuit chamber, and
the circuit board is fixed by being press-fitted to the plurality of protrusions.

3. The air flow rate measurement device according to claim 2, wherein
the cut part at the outer edge of the circuit board is arranged in the measurement passage of the housing.

4. The air flow rate measurement device according to claim 2, wherein
the fractured part at the outer edge of the circuit board is molded by resin forming the housing.

5. The air flow rate measurement device according to claim 2, further comprising: a cover that seals the circuit chamber with the housing.

6. The air flow rate measurement device according to claim 2, wherein a surface of the circuit board on which the electronic component is mounted is sealed with a potting agent.

7. The air flow rate measurement device according to claim 2, wherein
the cut part is positioned at outermost edges of the circuit board, and
the fractured part is provided at a position recessed inward from a virtual line connecting outermost edges of the circuit board.

8. A method of manufacturing an air flow rate measurement device configured to measure a flow rate of air flowing in a main passage comprising:
forming a multi-piece board that includes a plurality of circuit boards formed integrally with each other, wherein a detection element configured to output a signal in response to a flow rate of air and an electronic component configured to drive the detection element are mounted on the circuit board;
forming a cut part at an outer edge of the circuit board by processing the multi-piece board;
forming a fractured part at the outer edge of the circuit board by fracturing a part of the multi-piece board where the cut part is not formed so as to separate the circuit boards from each other;
forming a housing including a measurement passage for a part of the air flowing in the main passage, by injection molding; and
fixing the circuit board to the housing at a same time or after forming the housing by the injection molding to arrange the fractured part at a position excluding the measurement passage.

9. The method of manufacturing the air flow rate measurement device according to claim 8, further comprising:
molding the fractured part of the circuit board by resin forming the housing at the same time as the housing is formed by the injection molding.
